(19) United States
(12) Patent Application Publication
(10) Pub. No.: US 2012/0048465 A1
(43) Pub. Date: Mar. 1, 2012

(54) METHOD OF MANUFACTURING TOUCH SCREEN

(75) Inventors: Sang Hwa Kim, Gyunggi-do (KR); Jong Young Lee, Gyunggi-do (KR)

(73) Assignee: SAMSUNG ELECTRO-MECHANICS CO., LTD., Gyunggi-do (KR)

(21) Appl. No.: 12/941,238

(22) Filed: Nov. 8, 2010

(30) Foreign Application Priority Data
Aug. 30, 2010 (KR) 1020100084352

(51) Int. Cl. H05K 3/00

(52) U.S. Cl. 156/290

(57) ABSTRACT

Disclosed herein is a method of manufacturing a touch screen, including; preparing two sheets of transparent substrate on which transparent electrodes are formed; preparing a substrate on which a release film is formed; printing dot spacers on the release film and curing the dot spacers; transferring the dot spacers to the transparent electrode by stacking the substrate on the transparent substrate so that the dot spacers are in contact with the transparent electrode; and bonding the outer sides of the two sheets of transparent substrates by an adhesive layer so that the transparent electrodes formed on the two sheets of transparent substrates face each other. The dot spacers are previously cured on the release film and then transferred to the transparent electrode, thereby making it possible to prevent the transparent electrode from being damaged due to a curing process of the dot spacers.

### CROSS REFERENCE TO RELATED APPLICATION

This application claims the benefit of Korean Patent Application No. 10-2010-0084352, filed on Aug. 30, 2010, entitled “Method Of Manufacturing Touch screen”, which is hereby incorporated by reference in its entirety into this application.

### BACKGROUND OF THE INVENTION

1. Technical Field

The present invention relates to a method of manufacturing a touch screen.

2. Description of the Related Art

In particular, as electronic technology continuously develops, personal computers and portable transmitters etc. process texts and graphics, using a variety of input devices, such as a keyboard, a mouse, a digitizer, etc. These input devices, however, have been developed in consideration of the expanding usage of personal computers, such that they are difficult to be applied to portable devices that have been recently reduced in size and thickness. Therefore, touch screens are on the rise as an input device appropriate for the portable devices.

Touch screens, devices generally installed in display devices to select users' desired information, have various advantages of being simply operated with minimum malfunction in a small space while being very compatible with IT devices. Owing to these advantages, the touch screen is widely used in various fields such as industry, traffic, service, medicine, mobile, and the like.

Meanwhile, the touch screen is classifiable as a resistive type, a capacitive type, an electromagnetic type, a surface acoustic wave (SAW) type, an infrared type, and so on. Among others, the resistive type being relatively inexpensive and being able to accurately detect the positions of the touched input is widely used.

A resistive touch screen according to the prior art includes two sheets of transparent substrates, transparent electrodes formed on each of the transparent substrates, an adhesive layer bonding the two sheets of transparent substrates, and dot spacers formed on any one of the transparent electrodes.

Herein, the dot spacer is a member that mutually insulates the transparent electrodes formed on each of the two sheets of transparent substrates and provides repulsive force to return an upper transparent substrate to its original position when a touched input is released. The dot spacer is made of a transparent material having elasticity. The dot spacer may be formed by printing a material of the dot spacer on the transparent electrode formed on the transparent substrate and curing the material of the dot spacer by irradiating ultraviolet rays (UV) thereto.

However, the method of manufacturing the touch screen according to the prior art cures the dot spacers on the transparent electrode, thereby causing a problem. More specifically, ultraviolet rays are irradiated when the dot spacers are cured on the transparent electrode, such that sheet resistance of the transparent electrode may be increased, thereby damaging the transparent electrode. In particular, when the transparent electrode is made of a conductive polymer, the sheet resistance is significantly increased since the conductive polymer is more sensitive to ultraviolet rays or heat compared to indium tin oxide (ITO). In addition, the increase in sheet resistance or the like also causes a problem of failure in sensing whether a touched input is applied or which portion is touched even on the entire touch screen.

### SUMMARY OF THE INVENTION

The present invention has been made in an effort to provide a method of manufacturing a touch screen preventing a transparent electrode from being damaged by omitting a process of curing dot spacers on the transparent electrode.

A method of manufacturing a touch screen according to a preferred embodiment of the present invention includes: preparing two sheets of transparent substrates on which transparent electrodes are formed; preparing a substrate on which a release film is formed; printing dot spacers on the release film and curing the dot spacers; transferring the dot spacers to the transparent electrode by stacking the substrate on the transparent substrate so that the dot spacers are in contact with the transparent electrode; and bonding the outer sides of the two sheets of transparent substrates by an adhesive layer so that the transparent electrodes formed on the two sheets of transparent substrates face each other.

At this time, the release film is a film made of a silicon-based material or a Mylar film.

The transparent electrode includes a conductive polymer.

The transferring the dot spacers to the transparent electrode compresses and transfers the dot spacers to the transparent electrode.

The transferring the dot spacers to the transparent electrode applies heat of 80° C. or less.

At the bonding the two sheets of transparent substrates, the adhesive layer is a double adhesive tape (DAT).

The transparent electrodes formed on the two sheets of transparent substrates are in contact with each other when a touched input is generated to sense a change in resistance or voltage.

The substrate includes polyethyleneterephthalate (PET).

The transferring the dot spacers to the transparent electrode transfers the dot spacers to any one of the transparent electrodes formed on the two sheets of transparent substrates.

### BRIEF DESCRIPTION OF THE DRAWINGS

FIGS. 1 to 7 are process cross-sectional views for explaining a method of manufacturing a touch screen according to a preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

In the specification, in adding reference numerals to components throughout the drawings, it is to be noted that like reference numerals designate like components even though components are shown in different drawings. Further, terms used in the specification, ‘first’, ‘second’, etc. can be used to describe various components, but the components are not to be construed as being limited to the terms. The terms are only used to differentiate one component from other components. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

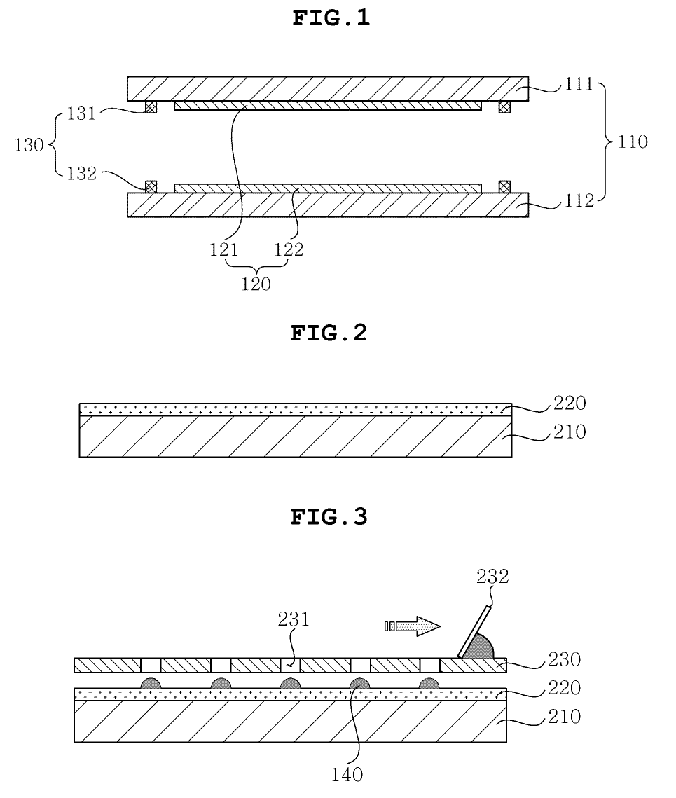

FIGS. 1 to 7 are process cross-sectional views for explaining a method of manufacturing a touch screen 100 according to a preferred embodiment of the present invention. Hereinafter, a method of manufacturing a touch screen 100 according to the present embodiment will be described with reference to these figures.

First, as shown in FIG. 1, two sheets of transparent substrates 110 on which transparent electrodes 120 are formed, respectively, are prepared.

At this time, the transparent substrate 110 may include a first transparent substrate 111 and a second transparent substrate 112. Any one of the first transparent substrate 111 and the second transparent substrate 112, which is a member receiving pressure from a specific object such as a user's body or a stylus pen, or the like, is preferably made of a material having elasticity so that it may be bent when pressure is applied and be returned to its original position when the pressure is released. For convenience of explanation, the present embodiment will describe a case in which the first transparent substrate 111 is the transparent substrate 110 receiving a touched input.

The first transparent substrate 111 may have a film type made of a transparent material having elasticity, for example, polyethyleneterephthalate (PET), polycarbonate (PC), polymethylmetacrylate (PMMA), polyethylenenaphthalate (PEN), polyethersulfone (PES) or cyclic olefin copolymer (COC). Besides, glass or tempered glass may be generally used. In addition, the second transparent substrate 112 may be made of the same transparent material as that of the first transparent substrate 111 but does not necessarily have elasticity as in the first transparent substrate 111. Meanwhile, since each of the transparent electrodes 120 is formed on the transparent substrate 110, it is preferable that one surface of the transparent substrate 110 is subjected to a high-frequency treatment or a primer treatment in order to improve the adhesion with the transparent electrode 120.

Meanwhile, a transparent electrode 121 may be formed on the first transparent substrate 111 and a second transparent electrode 122 may be formed on the second transparent substrate 112. Herein, the transparent electrodes 120 may be formed to have a bar type, orthogonal to each other so as to recognize an X-axis coordinate and a Y-axis coordinate, respectively. However, they are not limited thereto but they may also have various shapes such as a diamond shape, a hexagonal shape, an octagonal shape, a triangular shape, or the like. In addition, in a case of an analog resistive touch screen, the transparent electrode 120 may be formed to have a film type over the transparent substrate 110 except for edges of the transparent substrate 110.

In addition, it is preferable that the transparent electrodes 120 are made of a transparent material having conductivity for a user to be able to see the display easily under them when the touch screen 100 is completed. The transparent electrode 120 may, for example, be made of a conductive polymer containing poly-3, 4-ethylenedioxythiophene/polystyrenesulfonate (PEDOT/PSS), polyaniline alone or a mixture thereof, or metal oxides, such as indium tin oxide (ITO). At this time, when the transparent electrode 120 is made of a metal oxide, it may be coated on the transparent substrate 110 by deposition, development, etching and the like, and when the transparent electrode 120 is made of a conductive polymer, it may be formed on the transparent substrate 110 by silk screen printing, inkjet printing, gravure printing, offset printing, or the like.

The present embodiment describes a case in which the transparent substrates 110 on which the transparent electrodes 120 are formed are first prepared during a process of manufacturing the touch screen 100. However, those skilled in the art will understand that the process may be performed anytime before a process of transferring the dot spacers 140.

Meanwhile, electrodes 130 supplying voltage to the transparent electrodes 120 may further be formed on each of the transparent substrates 110. Herein, the electrode 130 is configured of a first electrode 131 and a second electrode 132, wherein the first electrode 131 may be formed on one surface of the first transparent substrate 111 to be connected to the first transparent electrode 121 and the second electrode 132 may be formed on one surface of the second transparent substrate 112 to be connected to the second transparent electrode 122. At this time, it is preferable that the electrode 130 is made of a material having excellent electrical conductivity so as to supply voltage to the transparent electrode 120. For example, the electrode 130 may be formed by printing a material composed of silver (Ag) paste or organic silver on the transparent substrate 110.

Next, as shown in FIG. 2, a substrate 210 on which a release film 220 is formed is prepared.

At this time, the substrate 210 may be a transparent substrate made of, for example, polyethyleneterephthalate (PET). However, the substrate 210 is not included in the constituents of the touch screen 100 such that the substrate 210 does not necessarily need to be transparent but may be a resin substrate made of, for example, epoxy resin or the like.

In addition, the release film 220 is a member that assists the dot spacers 140 in being easily separate from the substrate 210 when they are subsequently formed and are then transferred to the transparent electrode 120. Therefore, as the release film 220, a film made of a silicon-based material that is generally used or a Mylar film may be used.

Next, as shown in FIG. 3, the dot spacers 140 are printed on the release film 220 formed on the substrate 210.

At this time, the dot spacers 140 may be printed by, for example, a screen printing method. In this configuration, the screen printing method may be progressed in the following manner. First, a screen 230 formed with openings 231 is positioned over the release film 220 with the dot spacers 140, wherein the openings 231 are positioned to correspond to the dot spacers 140. Next, a material of the dot spacer 140 is put on a screen 230 in a state in which the screen 230 is tightly pulled by strong tension and the material of the dot spacer 140 is pushed to the surface of the release film 220 through the opening 231 of the screen 230 to be printed by pushing down and moving a squeegee 232. However, the printing of the dot spacers 140 is not limited to the screen printing method but may also be performed by other printing methods such as a gravure printing method or the like.

Meanwhile, the dot spacer 140 may use a photo curable and thermosetting resin, which is a transparent material having elasticity generally used, for example, acrylic resin or polyimide-based resin.

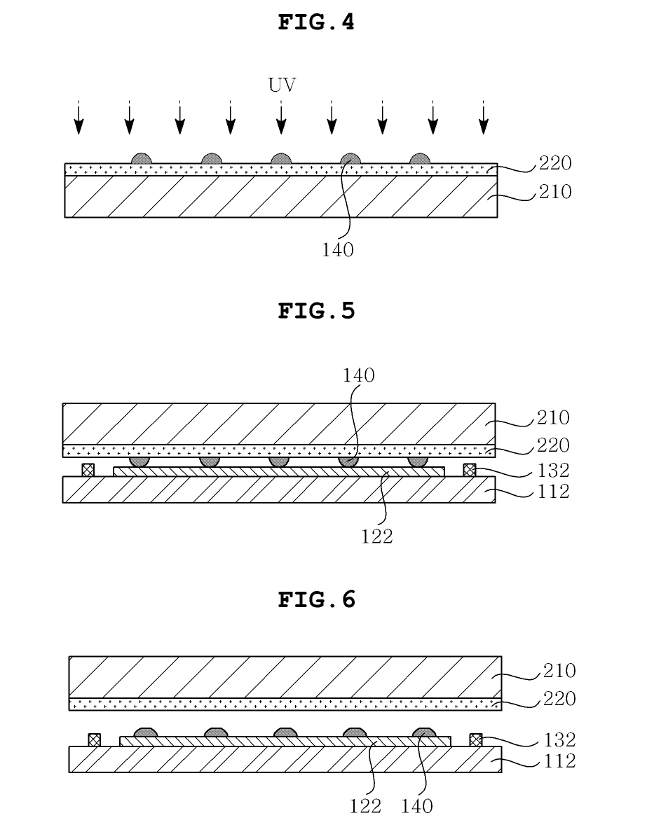

Next, as shown in FIG. 4, the dot spacers 140 printed on the release film 220 are cured.

At this time, a light source is positioned on the release film 220 on which the dot spacers 140 are printed and, for example, ultraviolet rays are irradiated thereto, thereby photocuring the dot spacers 140. In addition, when the dot spacer 140 is made of a thermosetting material, it may be cured by applying heat thereto.

Next, as shown in FIGS. 5 and 6, the cured dot spacers 140 are transferred to the transparent electrode 120.

At this time, the cured dot spacers 140 may be transferred to the second transparent electrode 122 by stacking the substrate 210 and the second transparent substrate 112 by way of example. The transferring process may be performed by applying pressure to the substrate 210 to compress the dot spacers 140 onto the second transparent electrode 122. Herein, when pressure is applied to the substrate 210, the cured dot spacers 140 are firmly adhered onto the second transparent electrode 122; however, the release film 220 has property to be easily detached. Therefore, when the dot spacers 140 are fixed onto the second transparent electrode 122 by compression, the release film 220 and the substrate 210 can be simply removed. In addition, some heat may be applied during the transferring process so as to firmly fix the dot spacers 140 onto the second transparent electrode 122. In this case, a temperature of the heat may be 80° C. or less. The reason is that if very high temperature heat is applied, it affects the second transparent electrode 122, as a result, sheet resistance of the second transparent electrode 122 may be increased.

Meanwhile, when the dot spacers 140 are compressed on the second transparent electrode 122 to be transferred, the top surfaces of the dot spacers 140 are supported by the release film 220 and the substrate 210 during the transferring process, such that the top surfaces of the plurality of dot spacers 140 transferred to the second transparent electrode 122 may have a uniform height. Therefore, when a touched input is applied, it is possible to sense a more accurate touch and prevent a phenomenon that stress is locally concentrated. In addition, the dot spacers 140 are previously cured on the release film 220 and are then transferred to the transparent electrode 120, such that the dot spacers 140 transferred to the transparent electrode 120 do not require a separate curing process. Therefore, there is no need to apply ultraviolet rays or high heat to the dot spacers 140, such that it is possible to prevent a phenomenon that the sheet resistance of the second transparent electrode 122 is increased. In particular, when the second transparent electrode 122 is made of a conductive polymer, the sheet resistance is sensitively changed by ultraviolet rays or heat. Therefore, when a separate curing process is omitted, it is possible to prevent a phenomenon that the sheet resistance is increased.

Meanwhile, although the present embodiment describes the case in which the dot spacers 140 are transferred to the second transparent electrode 122, the present invention is not limited thereto but may also include a case in which the dot spacers 140 are formed only on the first transparent electrode 121 or are formed on both the first transparent electrode 121 an the second transparent electrode 122.

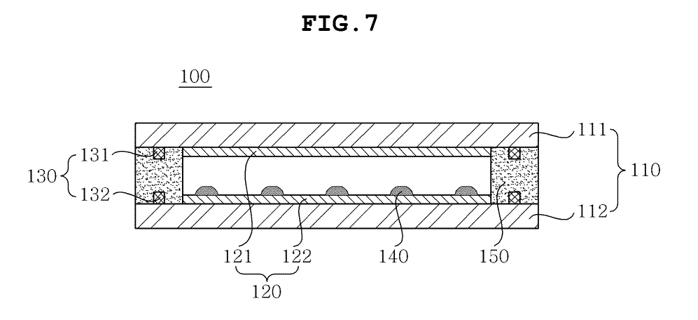

Next, as shown in FIG. 7, the second transparent substrate 112 on which the dot spacers 140 are formed is bonded to the first transparent substrate 111 by an adhesive layer 150.

At this time, a space in which the first transparent electrode 121 is in contact with the second transparent electrode 122 should be secured on the inner side between the first transparent substrate 111 and the second transparent substrate 112, such that the adhesive layer 150 may be formed on the outer side between the first transparent substrate 111 and the second transparent substrate 112. Therefore, since the adhesive layer 150 is formed in a bezel region, it is not necessarily required to be transparent but may be a double adhesive tape (DAT) by way of example.

Meanwhile, a separate window plate (not shown) may be formed on an upper portion of the first transparent substrate 111 to which a touched input is applied, thereby protecting the touch screen 100.

The touch screen 100 according to the preferred embodiment of the present invention as shown in FIG. 7 can be manufactured according to the manufacturing method as described above.

Herein, an operational method of the touch screen 100 according to the present embodiment will be described. When the touched input is applied to the touch screen 100, the first transparent substrate 111 and the first transparent electrode 121 are bent to the second transparent substrate 112. When the first transparent electrode 121 and the second transparent electrode are in contact with each other, a change occurs in resistance or voltage and a controller (not shown) may recognize the pressed coordinates based thereon. As a result, the controller (not shown) recognizes the coordinates of the pressed positions, thereby making it possible to implement a desired operation.

In addition, when the touched input is released, the first transparent substrate 111 and the first transparent electrode 121 may be returned to their original positions by receiving force from their own elasticity and elasticity of the dot spacer 140. Herein, the dot spacer 140 relieves the impact generated when the first transparent electrode 121 is in contact with the second transparent electrode 122 and provides repulsive force to return the first transparent substrate 111 to its original position when the pressure is released. In addition, the dot spacer 140 usually serves to maintain insulation between the transparent electrodes 120 so that the first transparent electrode 121 is not in contact with the second transparent electrode 122 when there is no external pressure.

The method of manufacturing a touch screen according to the present invention previously cures the dot spacers on the release film formed on the substrate and then transfers them to the transparent electrode, such that the curing process of the dot spacers on the transparent electrode is omitted, as a result, it is possible to prevent the transparent electrode from being damaged.

In addition, according to the present invention, the top surfaces of the dot spacers are supported by the release film and the substrate during the transferring process by using a method of compressing and transferring the dot spacers to the transparent electrode, such that the it is possible to form a plurality of dot spacers having a uniform height, as a result, it is possible to sense accurate positions of a touched input and prevent stress from being locally concentrated.

In addition, according to the present invention, heat of 80° C. or less is applied while the dot spacers are transferred to the transparent electrode, such that it is possible to improve adhesion between the dot spacers and the transparent electrode.

Although the preferred embodiments of the present invention have been disclosed for illustrative purposes, they are for specifically explaining the present invention and thus a method of manufacturing a touch screen according to the present invention is not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method of manufacturing a touch screen, comprising:
preparing two sheets of transparent substrates on which transparent electrodes are formed;
preparing a substrate on which a release film is formed;
printing dot spacers on the release film and curing the dot spacers;
transferring the dot spacers to the transparent electrode by stacking the substrate on the transparent substrate so that the dot spacers are in contact with the transparent electrode; and
bonding the outer sides of the two sheets of transparent substrates by an adhesive layer so that the transparent electrodes formed on the two sheets of transparent substrates face each other

2. The method of manufacturing a touch screen as set forth in claim 1, wherein the release film is a film made of a silicon-based material or a Mylar film.

3. The method of manufacturing a touch screen as set forth in claim 1, wherein the transparent electrode includes a conductive polymer.

4. The method of manufacturing a touch screen as set forth in claim 1, wherein the transferring the dot spacers to the transparent electrode compresses and transfers the dot spacers to the transparent electrode.

5. The method of manufacturing a touch screen as set forth in claim 1, wherein the transferring the dot spacers to the transparent electrode applies heat of 80° C. or less.

6. The method of manufacturing a touch screen as set forth in claim 1, wherein at the bonding the two sheets of transparent substrates, the adhesive layer is a double adhesive tape (DAT).

7. The method of manufacturing a touch screen as set forth in claim 1, wherein the transparent electrodes formed on the two sheets of transparent substrates are in contact with each other when a touched input is generated to sense a change in resistance or voltage.

8. The method of manufacturing a touch screen as set forth in claim 1, wherein the substrate includes polyethyleneterephthalate (PET).

9. The method of manufacturing a touch screen as set forth in claim 1, wherein the transferring the dot spacers to the transparent electrode transfers the dot spacers to any one of the transparent electrodes formed on the two sheets of transparent substrates.
